(19) United States
(12) Patent Application Publication
(10) Pub. No.: US 2003/0052720 A1
(43) Pub. Date: Mar. 20, 2003

(54) D-type latch with asymmetrical high-side MOS transistors for optical communication

(76) Inventors: John C. Tung, Cupertino, CA (US); Minghao (Mary) Zhang, Cupertino, CA (US)

Correspondence Address: C.P. Chang, c/o Pacific Law Group LLP, Suite 290, 2 North Second Street, San Jose, CA, 95113, US

(21) Appl. No.: 09/947,649

(22) Filed: Sep. 5, 2001

(51) Int. Cl. H03K 19/094

(52) U.S. Cl. 327/218

(57) ABSTRACT

A D-type latch with current mode switching using MOS transistors for high speed data communication without excessive noise and poor waveform jittering and a method of quantitative circuit design of such D-type latch circuit is presented. With this method, a value of electrically equivalent channel geometry is selected for the input pair of MOS transistors and a different value of electrically equivalent channel geometry is selected for the feedback pair of MOS transistors so as to reduce the resulting amount of output signal ringing as compared to a similar D-type latch circuit where the corresponding values of electrically equivalent channel geometry are equal. Furthermore, a set of output signal waveforms from a divide-by-2 counter and a divide-by-16 counter using the D-type latch as their building block are presented.

### FIELD OF THE INVENTION

The present invention relates generally to the field of data communication. More particularity, the present invention concerns the design of a new Complementary Metal Oxide Semiconductor (CMOS) Integrated Circuit (IC) that is capable of moving data up to a speed of 10 Gbit/Sec when implemented on Silicon with a standard 0.25 μm wafer process. Thus, its direct applications include certain key subsystem functions such as counter, Phase Detection (PD), Frequency Detection (FD), Phase and Frequency Detection (PFD) in an optical switch IC for data communication.

### BACKGROUND OF THE INVENTION

Optical Fiber has been used in voice and data communication for some time now due to its high bandwidth and excellent signal quality resulting from its immunity to electromagnetic interference. The inherent optical data rate from a modulated single-mode laser beam travelling through an optical fiber is expected to well exceed 10 Gbit/sec.

However, short of a completely optical communication system, the practically realizable bandwidth of fiber optical communication systems has been limited by the need of signal conversion between optical and electrical domain and the associated electronics hardware. The the usage of CMOS ICs has reached maturity in the electronics industry due to their advantage of low manufacturing cost, low operating power consumption, low supply voltage requirement while providing moderate speed in digital switching applications and fairly good circuit density. Because of these advantages, the fiber optical communication industry has attempted to use the CMOS technology as the preferred electronics hardware base to act as a switch for the optical signal as well. Unfortunately, due to the traditional speed limitation inherent in CMOS switches, previous attempts have been unsuccessful in creating an optical switch with a data rate of 10 Gbit/sec.

In addition, past attempts in identifying a modified CMOS wafer process to achieve the same goal has resulted in poor functional characteristics such as excessive noise, poor waveform jittering and the tendency of the operating IC to overheat quickly. Other technologies have been tried as well, with various degrees of success, in an attempt to achieve the desired speed. These include using materials other than pure Silicon such as Silicon Germanium (SiGe), Gallium Arsenide (GaAs), Indium Phosphide (InP) or using a hybrid device architect for the IC such as the combination of Bipolar and CMOS (BiCMOS), etc. Unfortunately these technologies all suffer from the major drawback of much higher manufacturing cost in terms of either high raw materials cost or high process cost with associated low yield.

The problem of high manufacturing cost is crucial, as it tends to discourage the deployment and use of these components, which in turn directly affects the growth and potential of the optical networking market. A direct impact to the consumer community is, due to this speed bottleneck, the failure to provide for the proper broadband requirement necessary for the delivery of web video and interactive TV in a multimedia environment. Thus, such inherent desire for broadband communication of the consumer community can only be met by realizing a “low cost” optical network for multimedia communication wherein an optical switch can be designed and made using standard, high volume and low cost IC manufacturing processes.

### SUMMARY OF THE INVENTION

The present invention is directed to the design of a high data rate, up to 10 Gbit/sec, and high signal quality D-type Latch CMOS IC as the fundamental building block of the aforementioned low cost optical switch within an optical network.

The first objective of this invention is to achieve a design of the subject D-type Latch CMOS IC with a much reduced amount of signal ringing after the respective logic signal levels are reached following a switching operation.

The second objective of this invention is to achieve a design of the subject D-type Latch CMOS IC that can be manufactured using standard, high volume and low cost CMOS wafer processes.

Other objectives, together with the foregoing are attained in the exercise of the invention in the following description and resulting in the embodiment illustrated in the accompanying drawings.

### BRIEF DESCRIPTION OF DRAWINGS

The present invention will be better understood and the nature of the objectives set forth above will become apparent when consideration is given to the following detailed description of the preferred embodiments. For clarity of explanation, the detailed description further makes reference to the attached drawings herein:

FIG. 1A and FIG. 1B show a standard circuit architecture of a D-type Latch with current mode switching and its associated logic functional block representation;

FIG. 2A is a logic functional block diagram of a Divide-by-2 Counter using the D-type Latch from FIG. 1B as its logic building block;

FIG. 2B is a logic functional block diagram of a Divide-by-2 Counter using the D-type Latch from FIG. 1B as its logic building block;

FIG. 3A shows a typical circuit schematic implementation of the D-type Latch of FIG. 1A;

FIG. 3B shows the circuit schematic implementation of the current invention for the D-type Latch of FIG. 1A;

FIG. 4A depicts a detailed output signal waveform, given a first input clock frequency, from the Divide-by-2 Counter of FIG. 2 whose logic building block of D-type Latch is quantitatively designed with a conventional practice;

FIG. 4B depicts a detailed output signal waveform, given a first input clock frequency, from the Divide-by-2 Counter of FIG. 2 whose logic building block of D-type Latch is quantitatively designed with the present invention;

FIG. 5A depicts a detailed output signal waveform, given a second input clock frequency, from the Divide-by-2 Counter of FIG. 2 whose logic building block of D-type Latch is quantitatively designed with a conventional practice;

FIG. 5B depicts a detailed output signal waveform, given a second input clock frequency, from the Divide-by-2 Counter of FIG. 2 whose logic building block of D-type Latch is quantitatively designed with the present invention;

FIG. 6A depicts a detailed output signal waveform, given a third input clock frequency, from the Divide-by-2 Counter of FIG. 2 whose logic building block of D-type Latch is quantitatively designed with a conventional practice; and

FIG. 6B depicts a detailed output signal waveform, given a third input clock frequency, from the Divide-by-2 Counter of FIG. 2 whose logic building block of D-type Latch is quantitatively designed with the present invention;

### DETAILED DESCRIPTION OF THE PREFERRED EMBODIMENTS

In the following detailed description of the present invention, numerous specific details are set forth in order to provide a thorough understanding of the present invention. However, it will become obvious to those skilled in the art that the present invention may be practiced without these specific details. In other instances, well known methods, procedures, components, and circuitry have not been described in detail to avoid unnecessary obscuring aspects of the present invention. The detailed description is presented largely in terms of logic blocks and other symbolic representations that directly or indirectly resemble the operations of signal processing devices coupled to networks. These descriptions and representations are the means used by those experienced or skilled in the art to most effectively convey the substance of their work to others skilled in the art.

Reference herein to “one embodiment” or an “embodiment” means that a particular feature, structure, or characteristics described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams representing one or more embodiments of the invention do not inherently indicate any particular order nor imply any limitations of the invention.

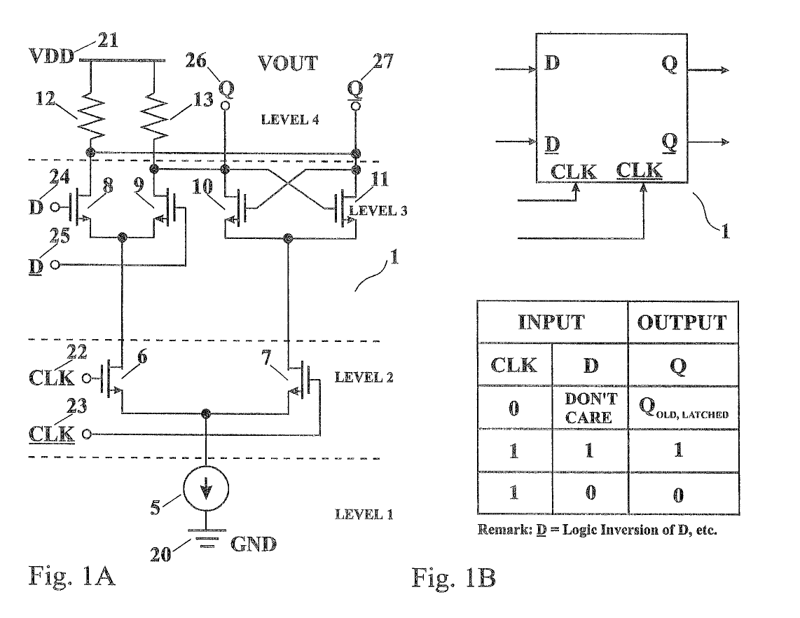

FIG. 1A shows a standard prior art conventional circuit architecture of a D-type Latch 1 with current mode switching. An associated logic functional block representation of the D-type Latch 1 are shown in FIG. 1B. For those skilled in the art, such a D-type Latch is manufacturable with a standard CMOS IC wafer process. However, if the D-type Latch 1 can further be quantitatively designed to provide a high quality signal output, then it can be used as the fundamental building block of a low cost optical switch for an optical network. At the architectural level, the circuitry is seen to be one of a traditional design with Current-Mode Logic (CML) and two major levels of signal switching, namely a lower level (LEVEL 2) and an upper level (LEVEL 3). The lower level is switched by two fastest clock signals CLK 22 and CLK 23 while the upper level is switched by two slower data signals D 24 and D 25. As an explanation of symbology, the data signal Dis defined to be the logic inversion of the data signal D, etc. The D-type Latch 1 is powered by a single supply with a voltage designation of VDD 21 for voltage and GND 20 for GROUND (0 Volt). To facilitate an understanding of the operation of this circuit architecture, dotted lines are used to partition the circuit into 4 levels. Namely LEVEL 1, LEVEL 2, LEVEL 3 and LEVEL 4, from bottom to top. LEVEL 1 consists of a Constant Current Source I1 that determines a driving current for the D-type Latch 1. LEVEL 2 consists of a Left Level-2 Transistor M1 and a Right Level-2 Transistor M2. These are differential transistors whose gates are driven respectively by the two fastest clock signals CLK 22 and CLK 23. With a design convention of the related art, the Left Level-2 Transistor M1 and the Right Level-2 Transistor M2 are also referred to as the lower level transistors. LEVEL 3, being also referred to as the upper level in the art, consists of four transistors. They are a Left Input Transistor M3, a Right Input Transistor M4, a Left Feedback Transistor M5 and a Right Feedback Transistor M6, being connected as two differential pairs. Among the set of four upper level transistors, the gates of the Left Input Transistor M3 and the Right Input Transistor M4 are respectively driven by the slower speed data signals D 24 and D 25. The Left Feedback Transistor M5 and the Right Feedback Transistor M6 are cross coupled and are known as the feedback transistor pair in the art. The last level, being called LEVEL 4, consists of a Left Pull-up Resistor R3 and a Right Pull-up Resistor R4. These resistors are the loads for the D-type Latch 1 and they determine the output signal voltage swing at nodes Q 26 and Q 27. It is remarked that the Left Pull-up Resistor R3 and the Right Pull-up Resistor R4 are not implemented with a PMOS transistor structure. Thus, the architecture of the D-type Latch 1 is not strictly that of a CMOS topology. Rather, the associated wafer process for the IC is that for a real CMOS IC.

During operation, when the CLK 22 is high, the input data D 24 and D 25 are enabled through the Left Input Transistor M1 and the Right Input Transistor M2 and the nodes Q 26 and Q 27 will track the input data D 24 and D 25. Meanwhile the CLK 23, being the logic inversion of the CLK 22, is low by definition. Thus, the Left Feedback Transistor M5 and the Right Feedback Transistor M6 are turned off through the action of the Right Level-2 Transistor M2. Later, when the CLK 22 goes low, the Left Input Transistor M3 and the Right Input Transistor M4 are turned off. Meanwhile, the CLK 23 goes high and it enables the cross coupled Left Feedback Transistor 10 and Right Feedback Transistor 11 to latch and hold the instantaneous logic state at nodes Q 26 and Q 27, or stated equivalently, to store the logic data at the Left Feedback Transistor M5 and the Right Feedback Transistor M6. Notice again that the Constant Current Source I1 is disposed in LEVEL 1 to provide the proper operating current for the whole circuit. Working with this operating current, the Left Pull-up Resistor R3 and the Right Pull-up Resistor R4 of LEVEL 4 are disposed to determine the output signal voltage swing at nodes Q 26 and Q 27. Thus, following conventions well known in the art, the associated logic functional block representation and truth table of the D-type Latch 1 are illustrated in FIG. 1B.

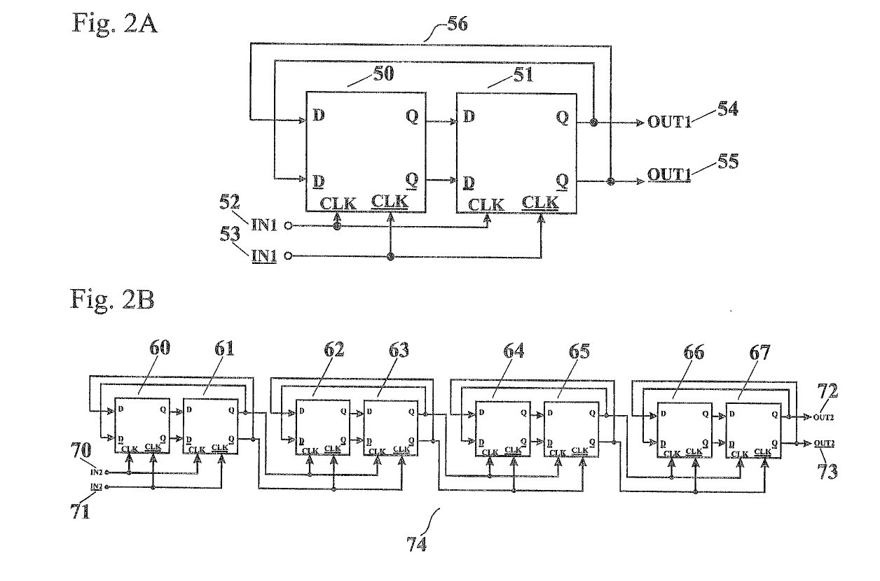

FIG. 2 is a logic functional block diagram of a Divide-by-2 Counter using the D-type Latch 1 from FIG. 1B as its logic building block. By cascading a D-type Latch 50 and a D-type Latch 51 with proper signal feedback connection from final output signals OUT1 54 and OUT1 55 to input terminals D and D of the first D-type Latch 50, the functionality of a Divide-by-2 Counter 56 is realized whereby the frequency of the output differential signal between the OUT1 54 and the OUT1 55 is made equal to one half of either one of input signals IN1 52 and IN153.

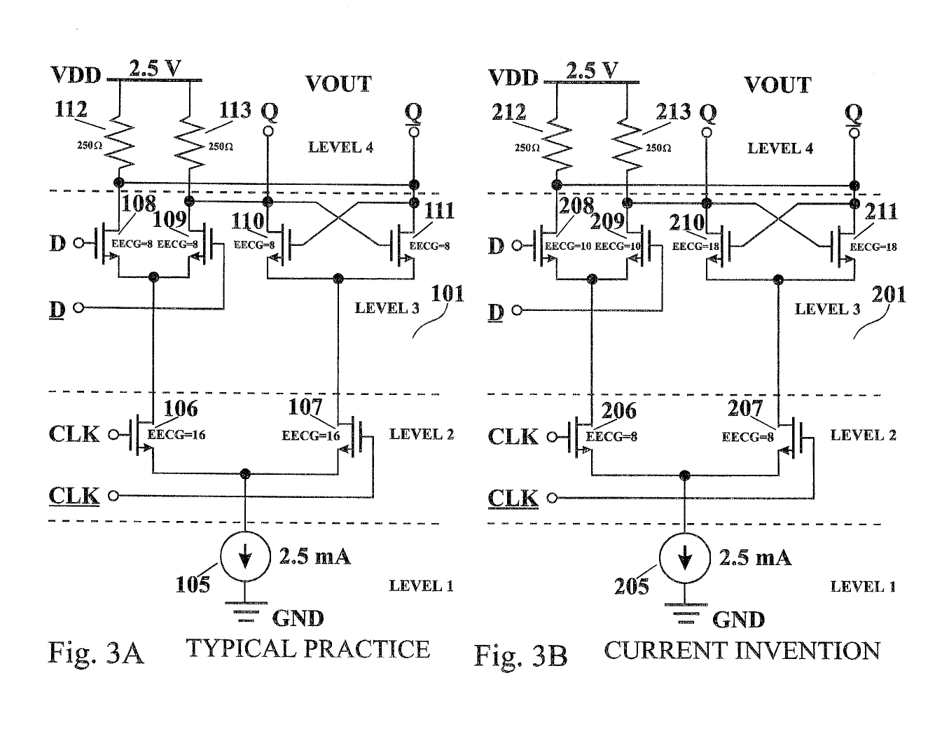

FIG. 3 shows a qualitative circuit schematic of the Divide-by-2 Counter 56 of FIG. 2. In this exemplary case the supply voltage VDD is shown to be 1.8 Volt although other values could be used just as well, for example 2.5 Volt. It is well known in the art that, at the IC-design level for a given wafer process, the conductance of an MOS transistor is primarily determined by the following parameter:

W/L, where W=channel width and L=channel length.

For convenience, the following parameter is defined:

Electrically Equivalent Channel Geometry (EECG)=W/L.

Given the above definition, a number of quantitative design examples for the qualitative circuit schematic of the Divide-by-2 Counter 56 between a conventional practice in the art and the present invention are compared.

TABLE 1 shows a first example of design comparison where the Divide-by-2 Counter 56 is quantitatively deigned to operate with an input IN1 52 of frequency 1.25 GHz. For example, with conventional practice, both the Left Level-2 Transistor M1 and the Right Level-2 Transistor M2 of the D-type Latch 50 have an EECG of 72. Likewise, with conventional practice, all of the Left Input Transistor M13, the Right Input Transistor M14, the Left Feedback Transistor M15 and the Right Feedback Transistor M16 of the D-type Latch 51 have an EECG of 36. It is also known in the art that, for the subject circuitry to function properly with high sensitivity, the EECG of the individual transistors must equal to each other within each differential transistor pair. That is, for the D-type Latch 50, the EECG of the Left Level-2 Transistor M1 should be equal to the EECG of the Right Level-2 Transistor M2, the EECG of the Left Input Transistor M3 should be equal to the EECG of the Right Input Transistor M4, and the EECG of the Left Feedback Transistor M5 should be equal to the EECG of the Right Feedback Transistor M6.

Similarly, for the D-type Latch 51, the EECG of the Left Level-2 Transistor M11 should be equal to the EECG of the Right Level-2 Transistor M12, the EECG of the Left Input Transistor M13 should be equal to the EECG of the Right Input Transistor M14, and the EECG of the Left Feedback Transistor M15 should be equal to the EECG of the Right Feedback Transistor M16.

TABLE 1
Design of EECG for DIV1DER 56 at: IN1 Frequency = 1.25 GHz

| | CONVENTIONAL | | PRESENT | |
|---|---|---|---|---|
| | PRACTICE | | INVENTION | |
| | | EECG | | EECG |
| D-Flip Flop 50 Level 2 | M1 | 72 | M1 | 54 |
| D-Flip Flop 50 Pair | M2 | 72 | M2 | 54 |
| D-Flip Flop 51 Level2 | M11 | 72 | M11 | 54 |
| D-Flip Flop 51 Pair | M12 | 72 | M12 | 54 |
| D-Flip Flop 50 Level 3 | M3 | 36 | M3 | 90 |
| D-Flip Flop 50 Input Pair | M4 | 36 | M4 | 90 |
| D-Flip Flop 50 Level 3 | M5 | 36 | M5 | 144 |
| D-Flip Flop 50 Feedback Pair | M6 | 36 | M6 | 144 |
| D-Flip Flop 51 Level 3 | M13 | 36 | M13 | 162 |
| D-Flip Flop 51 Input Pair | M14 | 36 | M14 | 162 |
| D-Flip Flop 51 Level 3 | M15 | 36 | M15 | 108 |
| D-Flip Flop 51 Feedback Pair | M16 | 36 | M16 | 108 |

While the above requirement is clearly satisfied by the conventional design practice as illustrated, it is important to point out that, according to the present invention, for the D-type Latch 50, the EECGs of the two transistor pairs within LEVEL 3 do NOT have to be equal. For example, as shown in TABLE 1, the EECGs of the pair of individual transistors consisting of Left Input Transistor M3 and Right Input Transistor M4 do not equal to the EECGs of the pair of individual transistors consisting of Left Feedback Transistor M5 and Right Feedback Transistor M6. Likewise, for the D-type Latch 51, the EECGs of the following two transistor pairs within LEVEL 3 also do NOT have to be equal according to the present invention. Thus, the EECGs of the pair of individual transistors consisting of Left Input Transistor M13 and Right Input Transistor M14 do not equal to the EECGs of the pair of transistors consisting of Left Feedback Transistor M15 and Right Feedback Transistor M16.

In fact, by purposely making the EECGs for the above two transistor pairs UNEQUAL, certain unique advantages are realized and this is the key concept of the present invention. More specifically, for D-type Latch 50, the “EECG of Left Input Transistor M3 and Right Input Transistor M4” is equal respectively to 90, but the “EECG of Left Feedback Transistor M5 and Right Feedback Transistor M6” is equal respectively to 144; and for D-type Latch 51, the “EECG of Left Input Transistor M13 and Right Input Transistor M14” is equal respectively to 162, but the “EECG of Left Feedback Transistor M15 and Right Feedback Transistor M16” is equal respectively to 108 as illustrated in TABLE 1. As shown above, by purposely making the EECG for the above two transistor pairs UNEQUAL, certain unique advantages are realized from the correspondingly increased freedom of design.

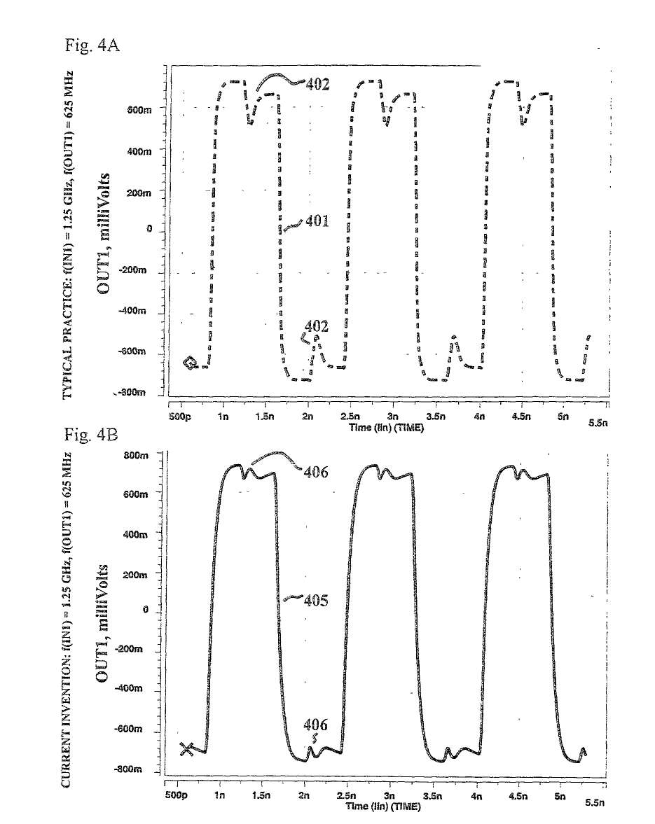

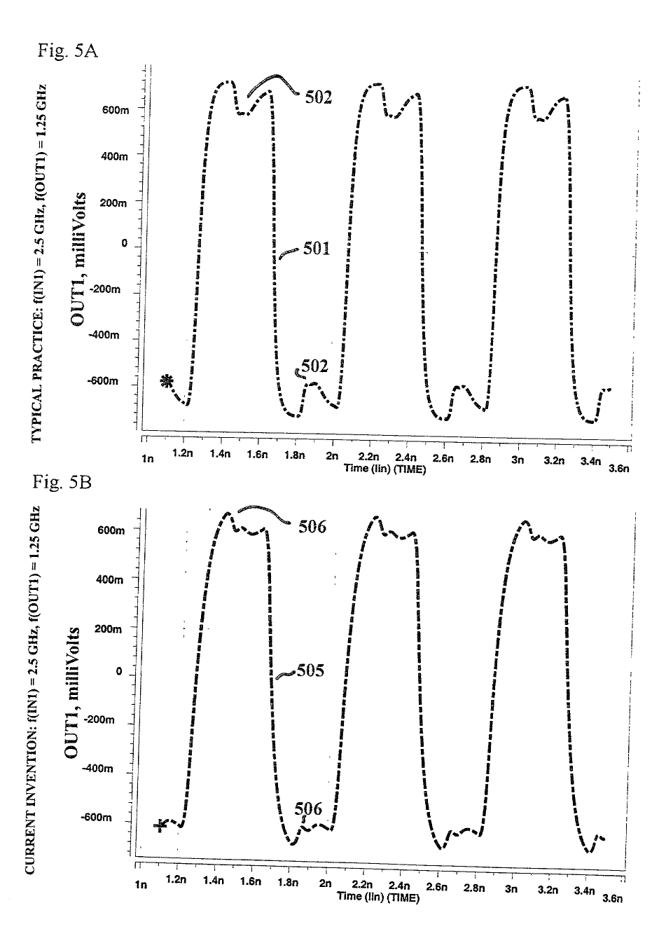

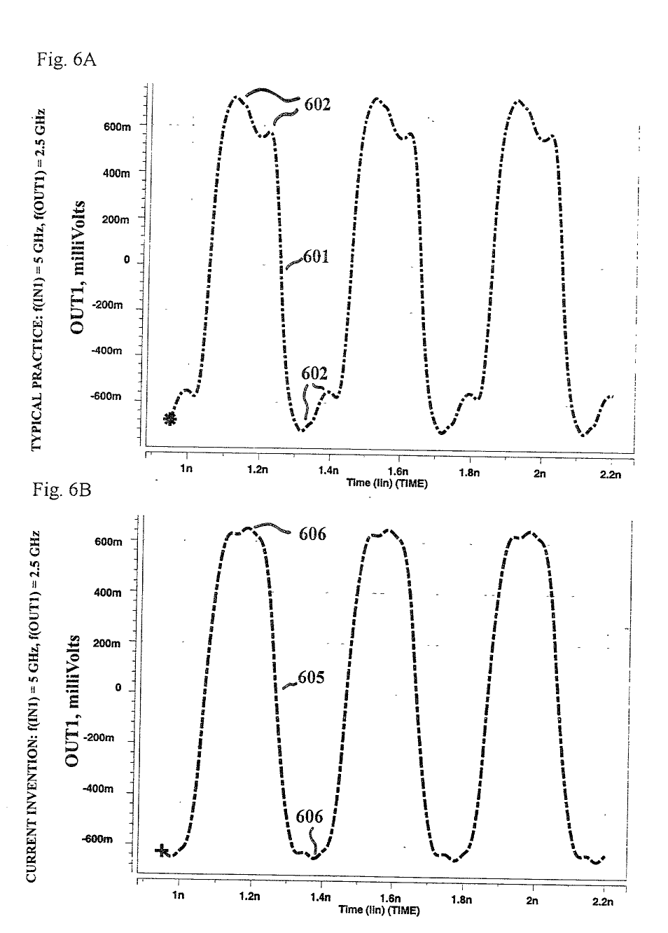

FIG. 4A depicts a detailed Differential Output Waveform 401 resulting from the conventional design practice of the Divide-by-2 Counter 56 operating for an input IN1 52 of frequency 1.25 GHz. For definition, the Divide-by-2 Counter Differential Output Waveform 401 is defined as the difference between Signal OUT1 and signal OUT1 as shown in FIG. 3. In addition, the waveform of all the input signals IN1 52, although NOT shown, should be understood to be a square wave of 50% duty cycle as will be shown throughout FIG. 4A, FIG. 4B, FIG. 5A, FIG. 5B, FIG. 6A and FIG. 6B. Observe that, with the conventional design practice, after the Differential Output Waveform 401 has reached its respective logic state, either high or low, a significant Signal Ringing 402 happens. This phenomenon is quite undesirable as the Signal Ringing 402, which may give rise to poor functional characteristics such as excessive noise and poor waveform jittering, will cause rejection of the subject IC by the data communication industry for reasons including a correspondingly lowered logic detection window and a lowered resistance against noise.

FIG. 4B depicts a detailed Differential Output Waveform 405 resulting from the present invention of the Divide-by-2 Counter 56 operating for an input IN1 52 of frequency 1.25 GHz. Notice that, by properly selecting an UNEQUAL value of EECGs for the aforementioned two transistor pairs of LEVEL 3, the corresponding amount of Signal Ringing 406 is vastly reduced.

Referring jointly to TABLE 2 and FIG. 5A, there depicts a detailed Differential Output Waveform 501 resulting from the conventional design practice of the Divide-by-2 Counter 56 operating for an input IN1 52 of frequency 2.5 GHz. Again, with the conventional schematic design, after the Differential Output Waveform 501 has reached its respective logic state, either high or low, a significant Signal Ringing 502 happens albeit the detailed signature of ringing looks different from before.

TABLE 2
Design of EECG for DIV1DER 56 at: IN1 Frequency = 2.5 GHz

| | CONVENTIONAL | | PRESENT | |
|---|---|---|---|---|
| | PRACTICE | | INVENTION | |
| | | EECG | | EECG |
| D-Flip Flop 50 Level 2 | M1 | 108 | M1 | 72 |
| D-Flip Flop 50 Pair | M2 | 108 | M2 | 72 |
| D-Flip Flop 51 Level 2 | M11 | 108 | M11 | 72 |
| D-Flip Flop 51 Pair | M12 | 108 | M12 | 72 |
| D-Flip Flop 50 Level 3 | M3 | 72 | M3 | 180 |
| D-Flip Flop 50 Input Pair | M4 | 72 | M4 | 180 |
| D-FIip Flop 50 Level 3 | M5 | 72 | M5 | 108 |
| D-Flip Flop 50 Feedback Pair | M6 | 72 | M6 | 108 |
| D-Flip Flop 51 Level 3 | M13 | 72 | M13 | 162 |
| D-Flip Flop 51 Input Pair | M14 | 72 | M14 | 162 |
| D-Flip Flop 51 Level 3 | M15 | 72 | M15 | 126 |
| D-Flip Flop 51 Feedback Pair | M16 | 72 | M16 | 126 |

Referring jointly to TABLE 2 and FIG. 5B, there depicts a detailed Differential Output Waveform 505 resulting from the present invention of the Divide-by-2 Counter 56 operating for an input IN1 52 of frequency 2.5 GHz. Notice again, by properly selecting an UNEQUAL value of EECGs for the aforementioned two transistor pairs of LEVEL 3, the corresponding amount of Signal Ringing 506 is vastly reduced.

Referring jointly to TABLE 3 and FIG. 6A, there depicts a detailed Differential Output Waveform 601 resulting from the conventional design practice of the Divide-by-2 Counter 56 operating for an input IN1 52 of frequency 5 GHz. Like before, with the conventional schematic design, after the Differential Output Waveform 601 has reached its respective logic state, either high or low, a significant Signal Ringing 602 happens albeit the detailed signature of ringing looks different from before.

TABLE 3
Design of EECG for DIV1DER 56 at: IN1 Frequency = 5 GHz

| | CONVENTIONAL | | PRESENT | |
|---|---|---|---|---|
| | PRACTICE | | INVENTION | |
| | | EECG | | EECG |
| D-Flip Flop 50 Level 2 | M1 | 144 | M1 | 72 |
| D-Flip Flop 50 Pair | M2 | 144 | M2 | 72 |
| D-Flip Flop 51 Level 2 | M11 | 144 | M11 | 72 |
| D-Flip Flop 51 Pair | M12 | 144 | M12 | 72 |
| D-Flip Flop 50 Level 3 | M3 | 72 | M3 | 108 |
| D-Flip Flop 50 Input Pair | M4 | 72 | M4 | 108 |
| D-Flip Flop 50 Level 3 | M5 | 72 | M5 | 198 |
| D-Flip Flop 50 Feedback Pair | M6 | 72 | M6 | 198 |
| D-FIip Flop 51 Level 3 | M13 | 72 | M13 | 90 |
| D-Flip Flop 51 Input Pair | M14 | 72 | M14 | 90 |
| D-Flip Flop 51 Level3 | M15 | 72 | M15 | 144 |
| D-Flip Flop 51 Feedback Pair | M16 | 72 | M16 | 144 |

Referring jointly to TABLE 3 and FIG. 6B, there depicts a detailed Differential Output Waveform 605 resulting from the present invention of the Divide-by-2 Counter 56 operating for an input IN1 52 of frequency 5 GHz. Notice again, by properly selecting an UNEQUAL value of EECGs for the aforementioned two transistor pairs of LEVEL 3, the corresponding amount of Signal Ringing 606 is vastly reduced to effectively eliminate the undesirable functional characteristics such as excessive noise and poor waveform jittering as seen in the otherwise conventional design practice for high speed data transmission as described above.

As described, by properly selecting a generally UNEQUAL value of Electrically Equivalent Channel Geometry (EECG) for the two MOS transistor pairs of LEVEL 3 within a circuit architecture of a D-type latch with current mode switching, the corresponding amount of signal ringing is vastly reduced. The present invention therefore provides a solution for a circuit architecture of a D-type latch manufacturable with the standard CMOS IC wafer process to achieve the benefits of low manufacturing cost, low operating power consumption, low supply voltage requirement while providing high speed in digital switching applications as desired by the high speed optical communication industry. Some of the related applications include, but not limited to, optical communication at 10 Gbit/sec data rate for OC48 and OC192, Gigabit Ethernet, 10 Gigabit Ethernet and Blue Tooth technology (2.4 GHz). At such a high data rate, the hardware infrastructure for a multimedia information super highway is also enabled.

The present invention has been described using exemplary preferred embodiments. However, for those skilled in this field, the preferred embodiments can be easily adapted and modified to suit additional applications without departing from the spirit and scope of this invention. For example, although not specifically illustrated herein, the same invention can be easily applied to the design a D-type latch employing emitter-coupled bipolar transistors as active switching elements with a corresponding improvement of signal ringing. Thus, it is to be understood that the scope of the invention is not limited to the disclosed embodiments. On the contrary, it is intended to cover various modifications and similar arrangements based upon the same operating principle. The scope of the claims, therefore, should be accorded the broadest interpretations so as to encompass all such modifications and similar arrangements.

We claim:

1. A D-type latch circuit with current mode switching using MOS transistors having a number of fast clock switches and a number of slower data switches for high speed data transmission without excessive noises, comprising:
a constant current source to provide a driving current;
a differential pair of transistors whose gates are driven by the fast clock signals; and
a plurality of MOS transistors consisting of a differential pair of data-input transistors and a differential pair of feedback transistors, whose gates are driven by the slower data signals wherein the value of an electrically equivalent channel geometry of the pair of data-input transistors is selected to be different from the value of an electrically equivalent channel geometry of the pair of feedback transistors in such a way that the resulting amount of output signal ringing is reduced as compared to a similar D-type latch circuit wherein the corresponding values of electrically equivalent channel geometry are selected to be equal.

2. The D-type latch circuit according to claim 1 further comprises a differential pair of pull-up resistors to provide a pair of output signal voltages.

3. The D-type latch circuit according to claim 1 wherein the high speed data transmission is in a range between 2.5 to 10 Gbit/sec data rate.

4. A semiconductor device comprising a plurality of D-type latch circuits cascaded thereof, wherein each of the D-type latch circuits employs a current mode switching scheme using MOS transistors having a number of fast clock switches and a number of slower data switches for high speed data transmission without excessive noises, each of the D-type latch circuits further comprising:
a constant current source to provide a driving current;
a differential pair of transistors whose gates are driven by the fast clock signals; and
a plurality of MOS transistors consisting of a differential pair of data-input transistors and a differential pair of feedback transistors, whose gates are driven by the slower data signals wherein the value of an electrically equivalent channel geometry of the pair of data-input transistors is selected to be different from the value of an electrically equivalent channel geometry of the pair of feedback transistors in such a way that the resulting amount of output signal ringing is reduced as compared to a similar D-type latch circuit wherein the corresponding values of electrically equivalent channel geometry are selected to be equal.

5. The semiconductor device according to claim 4 wherein each of the D-type latch circuits further comprises a differential pair of pull-up resistors to provide a pair of output signal voltages.

6. The semiconductor device according to claim 4 wherein the high speed data transmission is in a range between 2.5 to 10 Gbit/sec data rate.

7. The semiconductor device according to claim 4 wherein the semiconductor device is made of material selected from the group consisting of Si, Ge, SiGe, GaAs, and InP.

8. A method of quantitative circuit design of a D-type latch with current mode switching using MOS transistors having a number of fast clock switches and a number of slower data switches for high speed data transmission without excessive noises, comprising the steps of:
providing a constant current source to determine a driving current;
providing a differential pair of transistors whose gates are driven by the fast clock signals; and
selecting a plurality of MOS transistors consisting of a differential pair of data-input transistors and a differential pair of feedback transistors, whose gates are driven by the slower data signals, wherein the value of an electrically equivalent channel geometry of the pair of data-input transistors is selected to be different from the value of an electrically equivalent channel geometry of the pair of feedback transistors in such a way that the resulting amount of output signal ringing is reduced as compared to a similar D-type latch circuit wherein the corresponding values of electrically equivalent channel geometry are selected to be equal.

9. The method of quantitative circuit design of a D-type latch according to claim 8 further comprises the step of selecting a differential pair of pull-up resistors to provide a pair of output signal voltages.

10. The method of quantitative circuit design of a D-type latch according to claim 8 wherein the high speed data transmission is in a range between 2.5 to 10 Gbit/sec data rate.
